(19) United States
(12) Patent Application Publication
(10) Pub. No.: US 2010/0172515 A1
(43) Pub. Date: Jul. 8, 2010

(54) FILTER CIRCUIT

(75) Inventor: TOMINORI KIMURA, TOKYO (JP)

Correspondence Address: SUGHRUE MION, PLLC, 2100 PENNSYLVANIA AVENUE, N.W., SUITE 800, WASHINGTON, DC, 20037, US

(73) Assignee: KABUSHIKI KAISHA AUDIO-TECHNICA, TOKYO (JP)

(21) Appl. No.: 12/639,105

(22) Filed: Dec. 16, 2009

(30) Foreign Application Priority Data
Jan. 6, 2009 (JP) 2009-000987

(51) Int. Cl. H03G 5/00

(52) U.S. Cl. 381/97; 381/98

(57) ABSTRACT

A filter circuit includes: an input terminal; a first resistance; a second resistance; a capacitor; and an output terminal, in which the first resistance, the second resistance, and the capacitor are connected in series in this order between the input terminal and a ground point, the output terminal is provided at a connection point of the first resistance and the second resistance, and a frequency domain is used that is higher than a maximum phase delay frequency higher than a cutoff frequency, the cutoff frequency being determined by a combined resistance value of the first and the second resistances and a capacitance value of the capacitor, so that when a frequency of an input signal becomes higher, a phase delay of an output signal relative to the input signal is reduced.

### BACKGROUND OF THE INVENTION

1. Field of the Invention

The present invention relates to a filter circuit, and more specifically to a filter circuit using a frequency domain with which, as a frequency of an input signal becomes higher, a phase advance of an output signal relative to the input signal increases, and as the frequency of the input signal becomes lower, a phase difference between the input and the output signals reduces.

2. Description of the Related Art

Various filter circuits for processing audio signals are known. Such filter circuits are represented by a filter circuit using an analog circuit. Examples of the filter circuit using the analog circuit include: a low-pass filter circuit that passes only frequencies lower than a cutoff frequency; a high-pass filter circuit that passes only frequencies higher than the cutoff frequency; a band-pass filter circuit that passes only frequencies included in a frequency band defined by two cutoff frequencies; and a notch filter circuit that passes frequencies not included in the frequency band defined by the two cutoff frequencies. All the filter circuits listed above are difficult to be formed with an applicative coil because frequencies of audio signals to be processed thereby are low. Thus, the filter circuits are usually formed with a resistance and a capacitor.

An exemplary circuit configuration, a frequency characteristic, and a phase characteristic of a conventional filter circuit will be explained. FIG. 8 depicts an example of a low-pass filter circuit. As shown in FIG. 8, this conventional low-pass filter circuit is formed by: connecting a resistance R and a capacitor C in series in this order between an input terminal I and a ground point G; and providing an output terminal O at a connection point of the resistance R and the capacitor C. A cutoff frequency of the low-pass filter circuit formed as such is determined according to a time constant obtained from a resistance value of the resistance R and a capacitance value of the capacitor C. The frequency characteristic and the phase characteristic thereof are obtained by formulae shown in FIGS. 9A and 9B by a transfer function of the low-pass filter circuit.

As can be seen in FIG. 9A, the conventional low-pass filter circuit has a frequency characteristic in which an output signal level becomes lower when a frequency of an input signal becomes higher than the cutoff frequency. Further, as can be seen in FIG. 9B, the conventional low-pass filter circuit has a phase characteristic in which a phase of the output signal delays from that of the input signal when the frequency of the input signal becomes higher than the cutoff frequency. To sum it up, with the conventional low-pass filter circuit, as the frequency of the input signal becomes higher, the output signal level becomes lower and the phase delay of the output signal relative to the input signal is increased.

FIG. 10 depicts an example of a high-pass filter circuit. As shown in FIG. 10, this conventional high-pass filter circuit is formed by: connecting the capacitor C and the resistance R in series in this order between the input terminal I and the ground point G; and providing the output terminal O at the connection point of the capacitor C and the resistance R. A cutoff frequency of the high-pass filter circuit is determined according to the time constant obtained from the capacitance value of the capacitor C and the resistance value of the resistance R. A frequency characteristic and a phase characteristic thereof are obtained by formulae shown in FIGS. 11A and 11B by a transfer function of the high-pass filter circuit.

As can be seen in FIG. 11A, the conventional high-pass filter circuit has a frequency characteristic in which the output signal level becomes lower when the frequency of the input signal becomes lower than the cutoff frequency. Further, as can be seen in FIG. 11B, the conventional high-pass filter circuit has a phase characteristic in which the phase advance of the output signal relative to the input signal is increased when the frequency of the input signal becomes lower than the cutoff frequency. To sum it up, with the conventional high-pass filter circuit, when the frequency of the input signal becomes lower, the output signal level becomes lower and the phase advance of the output signal relative to the input signal increases.

Noise canceling headphones are known as an example of an apparatus using the filter circuit as described above. With the noise canceling headphones, a user can listen to music while canceling out surrounding noise. This is achieved by: collecting the surrounding noise with a microphone unit provided on a headphone casing or the like; converting the surrounding noise into an electrical signal (noise signal) with the microphone; generating, based on the noise signal, a signal (canceling signal) that cancels out noise passing through the headphone casing to be heard by the user; and outputting a canceling sound together with music from a speaker unit of the headphone.

Ideally, noise canceling headphones completely cancel out the noise. However, the microphone unit and the speaker unit have a phase characteristic in which phases thereof are displaced according to frequencies. More specifically, the phase characteristic is such that, when the frequency of the input signal becomes lower, the phase advance of the output signal relative to the input signal increases, and, when the frequency of the input signal becomes higher, the phase delay of the output signal relative to the input signal increases. Naturally, the canceling signal output from the speaker unit is affected by the phase characteristic. Therefore, a canceling signal that can completely cancel out a noise heard through user's ears is difficult to be generated. The canceling sound, emitted from the speaker unit, having a phase displaced by being affected by the phase characteristic not only degrades the canceling sound's original effect of canceling out a noise (canceling effect), but also may amplify certain frequencies in the noise to make the noise louder to be heard.

The phase displacement as described above may be caused by other reasons. The surrounding noise is composed of various sounds, that is, the surrounding noise has a large bandwidth. Thus, a canceling signal effective to the large bandwidth is required to generate canceling sound for all the frequencies included in the noise. Actually, generation of such canceling signal is difficult. Therefore, the noises that should especially be canceled out are exclusively chosen with the filter circuit.

However, as describe above, the filter circuit has the phase characteristic similar to those of the microphone unit and the speaker unit. Thus, the filter circuit cannot be expected to correct the phase displacement. Accordingly, in the conventional noise canceling headphones, a plurality of filter circuits are used in combination so as to make phase characteristics appear to be completed each other. However, as described above, use of a plurality of the conventional filter circuits limits the frequency band within which the noise can be canceled out. As a technique to solve the problem and allow a user to cancel out various noises, a noise canceling system is known that can increase the type of noises that can be canceled out by incorporating a plurality of filter circuits and selectively switching therebetween with a switch and the like (see, for example Japanese Patent Application Publication No. 4-8099).

There are two types of filter circuit: a passive type using a passive element; and an active type using an operational amplifier and the like. In both types of filter circuits, with a lower frequency component, the phase advance of the output signal relative to the input signal increases, and with a higher frequency component, the phase delay of the output signal relative to the input signal increases.

As described above, the filter circuit formed with a resistance and a capacitor is well known in which, when the frequency of the input signal becomes higher, the phase delay of the output signal relative to the input signal increases. However, a filter circuit has not been available that allows the user to utilize its characteristic in which, when the frequency of the input signal becomes higher, the phase advance of the output signal relative to the input signal increases.

### SUMMARY OF THE INVENTION

In view of the above, an object of the present invention is to provide a filter circuit that allows a user to utilize its characteristic in which, when a frequency of an input signal becomes higher, a phase advance of the output signal relative to the input signal increases.

A filter circuit according to an aspect of the present invention includes: an input terminal; a first resistance; a second resistance; a capacitor; and an output terminal. The first resistance, the second resistance, and the capacitor are connected in series in this order between the input terminal and a ground point. The output terminal is provided at a connection point of the first resistance and the second resistance. A frequency domain is used that is higher than a maximum phase delay frequency higher than a cutoff frequency. The cutoff frequency is determined by a combined resistance value of the first and the second resistances and a capacitance value of the capacitor. Thus, when a frequency of an input signal becomes higher, a phase delay of an output signal relative to the input signal is reduced.

In the filter circuit according to the aspect of the present invention, resistance values of the first and the second resistances may be determined based on a certain ratio.

The filter circuit according to the aspects of the present invention may further include: a positive phase amplifier for amplifying and outputting a signal output from the output terminal; an inverting amplifier for amplifying and outputting a signal received from the input terminal; and an adder for adding and outputs the output from the positive phase amplifier and the output from the inverting amplifier.

A filter circuit according to another aspect of the present invention includes: an input terminal; a variable resistance having three terminals; a capacitor; and an output terminal. The variable resistance and the capacitor are connected in series in this order between the input terminal and a ground point. The output terminal is provided at an intermediate terminal of the variable resistance. A frequency domain is used that is higher than a maximum phase delay frequency higher than a cutoff frequency. The cutoff frequency is determined by a resistance value of the variable resistance and a capacitance value of the capacitor. Thus, when a frequency of an input signal becomes higher, a phase delay of an output signal relative to the input signal is reduced.

The filter circuit according to the aspects of the present invention may further include: a positive phase amplifier for amplifying and outputting a signal output from the output terminal; an inverting amplifier for amplifying and outputting a signal received from the input terminal; and an adder for adding and outputs the output from the positive phase amplifier and the output from the inverting amplifier.

A filter circuit according to still another aspect of the present invention includes: an input terminal; a first capacitor; a second capacitor; a resistance; and an output terminal. The first capacitor, the second capacitor, and the resistance are connected in series in this order between the input terminal and a ground point. The output terminal is provided at a connection point of the first capacitor and the second capacitor. A frequency domain is used that is lower than a maximum phase advance frequency lower than a cutoff frequency. The cutoff frequency is determined by a combined capacitance value of the first and the second capacitors and a resistance value of the resistance. Thus, when a frequency of an input signal becomes lower, a phase advance of an output signal relative to the input signal is reduced.

In the filter circuit of the aspect of the present invention, capacitance values of the first and the second capacitors may be determined based on a certain ratio.

The present invention provides a filter circuit capable of correcting a conventional phase characteristic of an acoustic system in which a phase is displaced according to frequency levels, thereby enabling a natural audio processing.

### BRIEF DESCRIPTION OF THE DRAWINGS

FIG. 1 is a circuit diagram depicting an embodiment of a low-pass filter circuit as an example of a filter circuit according to the present invention;

FIG. 2 is a circuit diagram depicting another embodiment of the low-pass filter circuit;

FIG. 3A depicts a formula to obtain a frequency characteristic of the low-pass filter circuit shown in FIG. 1;

FIG. 3B depicts a formula to obtain a phase characteristic of the low-pass filter circuit shown in FIG. 1;

FIG. 3C depicts a formula to obtain a maximum phase delay frequency of the low-pass filter circuit shown in FIG. 1;

FIG. 3D depicts a formula to obtain a maximum phase delay angle of the low-pass filter circuit shown in FIG. 1;

FIG. 4 is a circuit diagram depicting an embodiment of a high-pass filter circuit as an example of a filter circuit according to the present invention;

FIG. 5A depicts a formula to obtain a frequency characteristic of the high-pass filter circuit shown in FIG. 4;

FIG. 5B depicts a formula to obtain a phase characteristic of the high-pass filter circuit shown in FIG. 4;

FIG. 5C depicts a formula to obtain a maximum phase delay frequency of the high-pass filter circuit shown in FIG. 4;

FIG. 5D depicts a formula to obtain a maximum phase delay angle of the high-pass filter circuit shown in FIG. 4;

FIG. 6 is a circuit diagram depicting an embodiment of an active low-pass filter circuit as an example of the filter circuit of the present invention;

FIG. 7A depicts a formula to obtain a frequency characteristic of the low-pass filter circuit shown in FIG. 6;

FIG. 7B depicts a formula to obtain a phase characteristic of the low-pass filter circuit shown in FIG. 6;

FIG. 7C depicts a formula to obtain a maximum phase delay frequency of the low-pass filter circuit shown in FIG. 6;

FIG. 7D depicts a formula to obtain a maximum phase delay angle of the low-pass filter circuit shown in FIG. 6;

FIG. 8 is a circuit diagram depicting an example of a conventional low-pass filter circuit;

FIG. 9A depicts a formula to obtain a frequency characteristic of the conventional low-pass filter circuit;

FIG. 9B is depicts formula to obtain a phase characteristic of the conventional low-pass filter circuit;

FIG. 10 is a circuit diagram depicting an example of a conventional high-pass filter circuit;

FIG. 11A depicts a formula to obtain a frequency characteristic of the conventional high-pass filter circuit; and

FIG. 11B depicts a formula to obtain a phase characteristic of the conventional high-pass filter circuit.

### DETAILED DESCRIPTION OF THE PREFERRED EMBODIMENTS

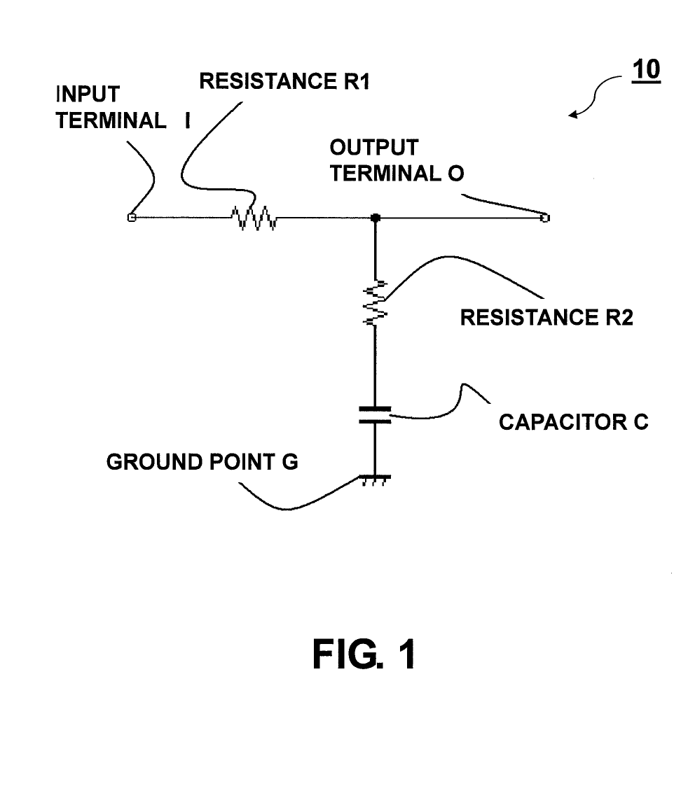

Preferred embodiments of a filter circuit according to the present invention are described with reference to the accompanying drawings. FIG. 1 is a circuit diagram exemplary depicting a low-pass filter circuit as an example of the filter circuit according to the present invention.

### First Embodiment

In FIG. 1, this low-pass filter circuit 10 is formed by: connecting a resistance R1, a resistance R2, and a capacitor C in series in this order between an input terminal I and a ground point G; and providing an output terminal O that picks up an output signal at a connection point of the resistance R1 (first resistance) and the resistance R2 (second resistance). A cutoff frequency fclp of the low-pass filter circuit 10 is determined according to a time constant obtained from: a combined resistance value R of the resistance R1 and the resistance R2, i.e., R1+R2; and a capacitance value of the capacitor C.

An output level of the low-pass filter circuit 10 can be obtained through the following formula:

√((1+(2πfCR2)²))/(1+(2πfC(R1+R2))²)

Here, “f” denotes a frequency of an input signal. As with the conventional low-pass filter circuit, the low-pass filter circuit 10 attenuates frequencies higher than the cutoff frequency fclp. Moreover, when the frequency of the input signal is higher than the cutoff frequency, an impedance of the capacitor C, which becomes smaller as the frequency of the input signal becomes higher, becomes vanishingly small relative to the resistance R2. Thus, in a frequency domain equal to or higher than a maximum phase delay frequency (certain frequency) that is higher than the cutoff frequency fclp, the output of the low-pass filter circuit 10 is attenuated down to its maximum R2/(R1+R2) of the input signal. Here, because the impedance of the capacitor C is small enough to be ignored, the phase of the output signal gradually returns to 0 degrees (output signal becomes in-phase with the input signal). As described above, by using the frequency band equal to or higher than the maximum phase delay frequency in the low-pass filter circuit 10 of the present invention, a low-pass filter circuit can be obtained in which, when the frequency of the input signal becomes higher, the phase advance of the output signal relative to the input signal increases.

Further, in the low-pass filter circuit 10 according to the present invention, as the frequency of the input signal becomes lower, the phase delay of the output signal relative to the input signal is generated, increased, and becomes the largest at the maximum phase delay frequency. Accordingly, a filter circuit can be obtained that can correct the characteristic of a head phone unit and a microphone unit in which, when the frequency of the input signal becomes lower, the output level becomes lower and the phase advance of the output signal relative to the input signal increases, by setting the maximum phase delay frequency sufficiently low relative to a frequency included in a signal subjected to a filter processing.

The resistance values of the resistances R1 and R2 may be arbitrary set or, with a resistance ratio Nr, may be set as: R1=Nr·R; and R2=(1−Nr)·R (here, 0≦Nr≦1). Thus, the maximum attenuation of the input signal can be controlled with the resistance ratio Nr.

### Second Embodiment

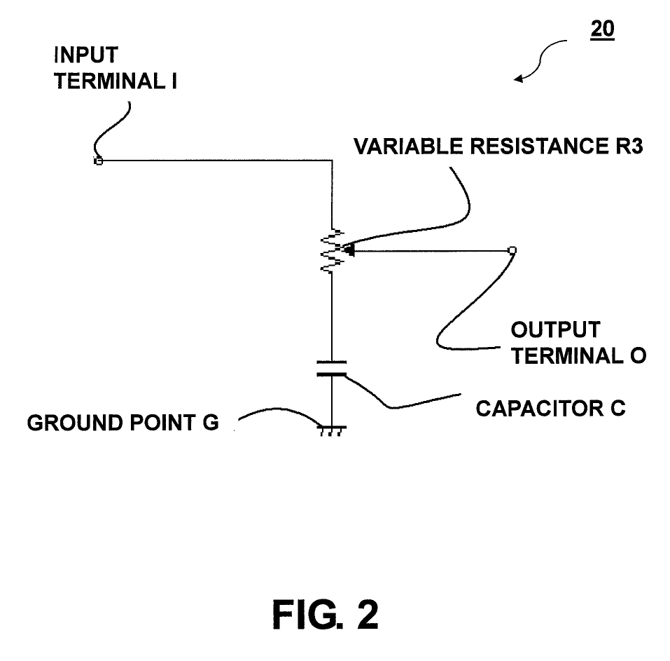

Another embodiment of the filter circuit of the present invention is shown in FIG. 2. A low-pass filter circuit 20 shown in FIG. 2 has, in place of the resistances R1 and R2 provided in the low-pass filter circuit 10, a variable resistance R3. In the low-pass filter circuit 20, the output terminal O is provided at a movable terminal of the variable resistance R3.

Thus, ratio of a resistance dividing the voltage of the input signal is variable by changing the position of the movable terminal. As a result, the low-pass filter 20 can provide the same effect as provided by the low-pass filter 10 by setting the resistance values of the resistances R1 and R2 with the certain resistance ratio Nr as in the first embodiment. Therefore, the filter circuit having the optimal phase characteristic can easily be obtained.

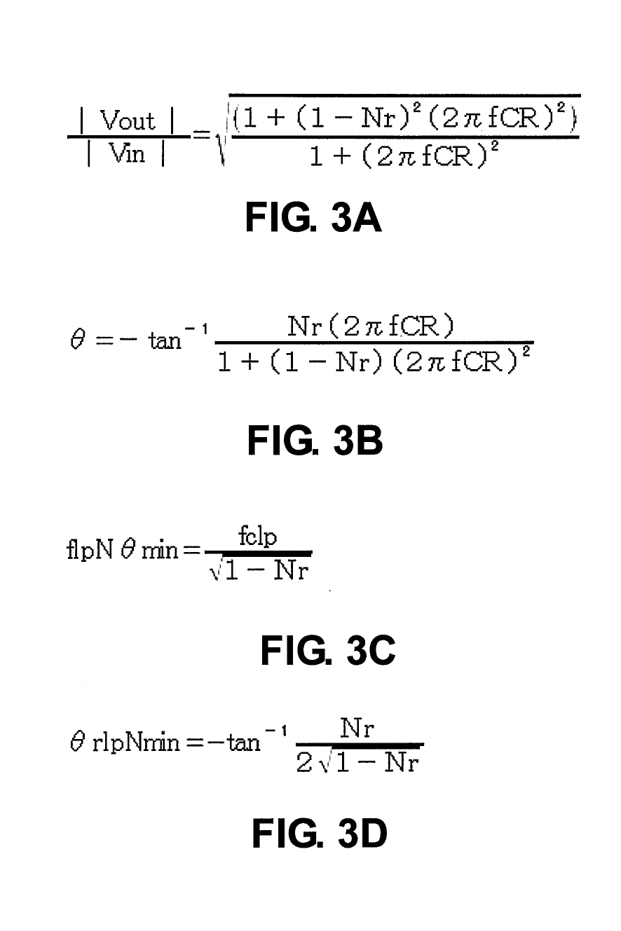

The maximum phase delay frequency will be explained. In the filter circuit of the present invention, as the frequency of the input signal becomes higher, the phase of the output signal starts to advance from that of the input signal at the maximum phase delay frequency. FIGS. 3A to 3D are formulae depicting: a frequency characteristic; a phase characteristic; a maximum phase delay frequency; and a maximum phase delay angle, respectively, obtained by a transfer function of the filter circuit 10 according to the first embodiment. According to the frequency characteristic shown in FIG. 3A, when resistance ratio (Nr) of the resistances of the low-pass filter circuit 10 becomes closer to 1, the output level becomes lower as the frequency of the input signal becomes higher. According to the phase characteristic shown in FIG. 3B, the phase delay is 0 degree (output signal is in-phase with the input signal) when the frequency is zero, and as the frequency of the input signal becomes higher, the phase delay is generated, increased, and then returns to 0 degree (output signal becomes in-phase with the input signal). The maximum phase delay frequency in the filter circuit can be obtained, relative to the cutoff frequency fclp, by dividing the cutoff frequency fclp with the square root of the value obtained by subtracting the resistance ratio Nr from 1, as shown in FIG. 3C.

Similarly, as shown in FIG. 3D, the maximum phase delay angle of the maximum phase delay frequency is obtained based on the resistance ratio Nr.

Accordingly, a low-pass filter circuit can be obtained in which, unlike the conventional low-pass filter circuit, when the frequency of the input signal becomes higher, the phase advance of the output signal relative to the input signal increases by using, as the low-pass filter circuit, the filter circuit of the present invention and appropriately selecting the resistance values of the two resistance elements to use the frequency domain higher than the maximum phase delay frequency.

### Third Embodiment

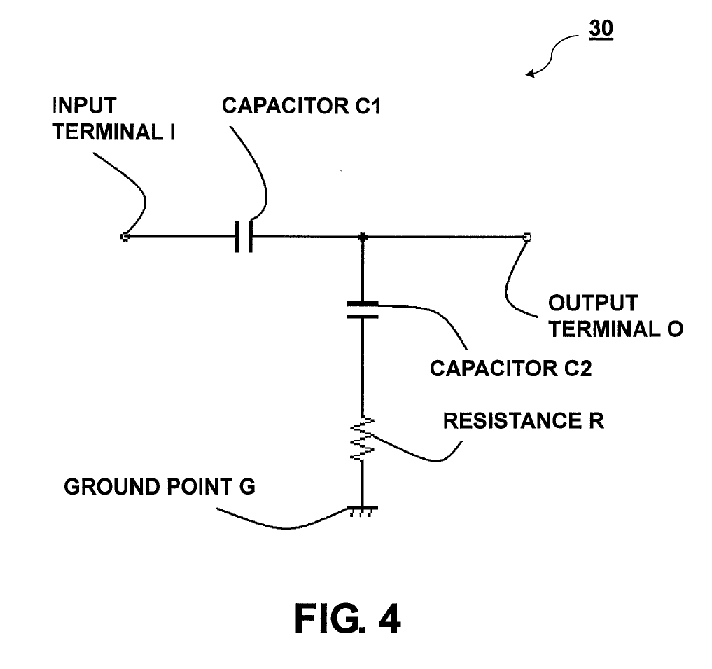

Still another embodiment of the filter circuit according to the present invention will be described. FIG. 4 is a circuit diagram depicting an example of a high-pass filter circuit as an example of the filter circuit according to the present invention. As shown in FIG. 4, this high-pass filter circuit 30 is formed by: connecting a capacitor C1, a capacitor C2, and a resistance R in series in this order between the input terminal I and the ground point G; and providing the output terminal O that picks up the output signal at a connection point of the capacitor C1 and the capacitor C2. A cutoff frequency fchp of the high-pass filter circuit 30 is determined based on a time constant obtained from: a combined capacitance value of the capacitor C1 and the capacitor C2, i.e., C1+C2; and a resistance value of the resistance R.

Similar to the conventional high-pass filter circuit, the high-pass filter circuit 30 outputs a frequency component higher than the cutoff frequency fchp, and attenuates a frequency component lower than the cutoff frequency fchp. A phase of the output signal advances from that of the input signal when the frequency of the input signal is low. The output signal becomes in-phase with the input signal as the frequency of the input signal becomes higher. Therefore, as the frequency of the input signal becomes higher, the phase of the output signal delays from that of the input signal. However, in a frequency domain that is lower than the cutoff frequency fchp and a maximum phase advance frequency (certain frequency), when the frequency of the input signal becomes lower, the output level becomes higher and the phase of the output signal delays from that of the input signal.

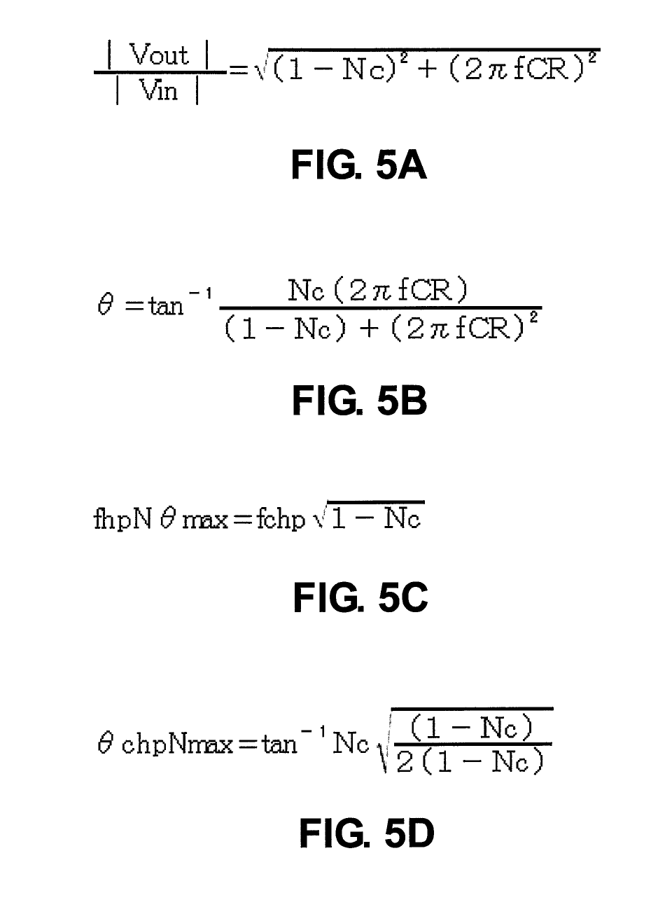

FIGS. 5A to 5D are formulae depicting: a frequency characteristic; a phase characteristic; a maximum phase advance frequency; and a maximum phase advance angle, respectively, obtained by a transfer function of the high-pass filter circuit 30. According to the frequency characteristic shown in FIG. 5A, when a capacitance ratio (Nc) of the capacitors of the high-pass filter circuit 30 is closer to 1, output level becomes low when the frequency of the input signal becomes low. According to the phase characteristic shown in FIG. 5B, the phase advance is 0 degree (output signal is in-phase with the input signal) when the frequency is zero, and as the frequency of the input signal becomes higher, the phase advance is generated, increased, and then returns to 0 degree. The maximum phase advance frequency can be obtained, relative to the cutoff frequency fchp, by multiplying the cutoff frequency fchp with the square root of the value obtained by subtracting the capacitance ratio Nc from 1, as shown in FIG. 5C.

Similarly, as shown in FIG. 5D, the maximum phase advance angle of the maximum phase advance frequency is obtained based on the capacitance ratio Nc.

Accordingly, a high-pass filter circuit can be obtained in which, unlike the conventional high-pass filter circuit, when the frequency of the input signal becomes higher, the phase advance of the output signal relative to the input signal increases by using, as the high-pass filter circuit, the filter circuit of the present invention and appropriately setting the capacitance values of the two capacitors to use the frequency domain lower than the maximum phase advance frequency.

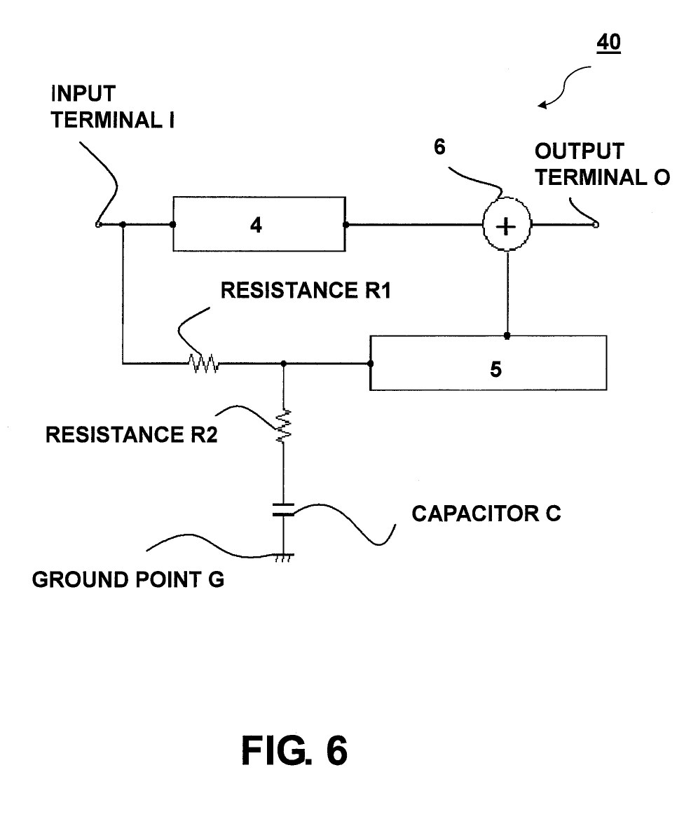

Yet still another embodiment of the present invention will be described. FIG. 6 is a circuit diagram of an active type low-pass filter circuit as an example of the filter circuit of the present invention. As shown in FIG. 6, this low-pass filter circuit 40 is formed by: connecting the resistance R1, the resistance R2, and the capacitor C in series in this order between the input terminal I and the ground point G; connecting an inverting amplifier 4 and an adder 6 between the input terminal I and the output terminal O; and connecting a positive phase amplifier 5 between the connection point of the resistances R1 and R2, and the adder 6. Therefore, it can be construed that the positive phase amplifier 5 receives the output from the low-pass filter circuit 10 in the first embodiment.

The inverting amplifier 4 amplifies the received signal and inverts the phase thereof and outputs resultant signal, and has an amplification degree of “A” times. The positive phase amplifier 5 amplifies the received signal by a certain value (1+A), i.e., has an amplification degree of (1+A) times, and outputs the resultant signal without inverting the phase thereof. The adder 6 adds and sends the outputs from the inversion amplifier 4 and the positive phase amplifier 5 to the output terminal O.

A cutoff frequency fcA of the low-pass filter circuit 40 is determined by the time constant obtained from: the combined resistance value R of the resistances R1 and R2, i.e., R1+R2; and the capacitance value of the capacitor C. As in the first embodiment, the resistance values of the resistances R1 and R2 may be set with the certain resistance ratio Nr.

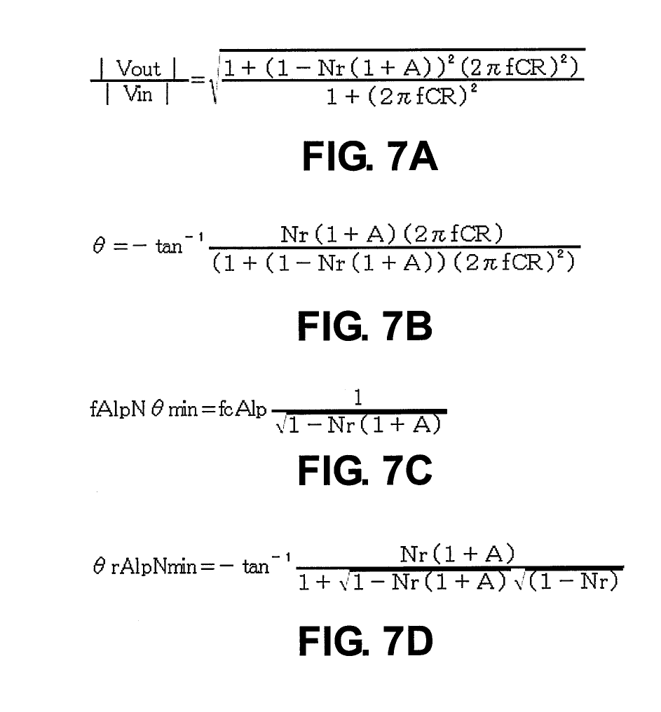

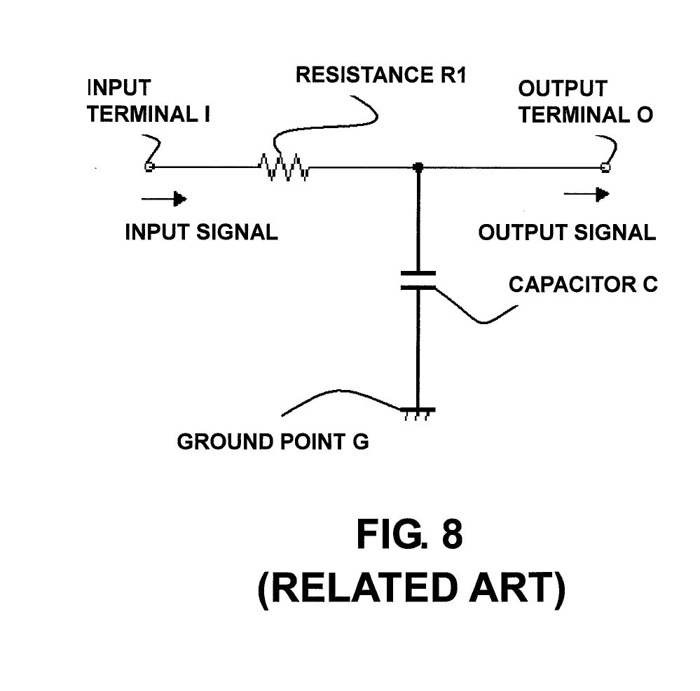

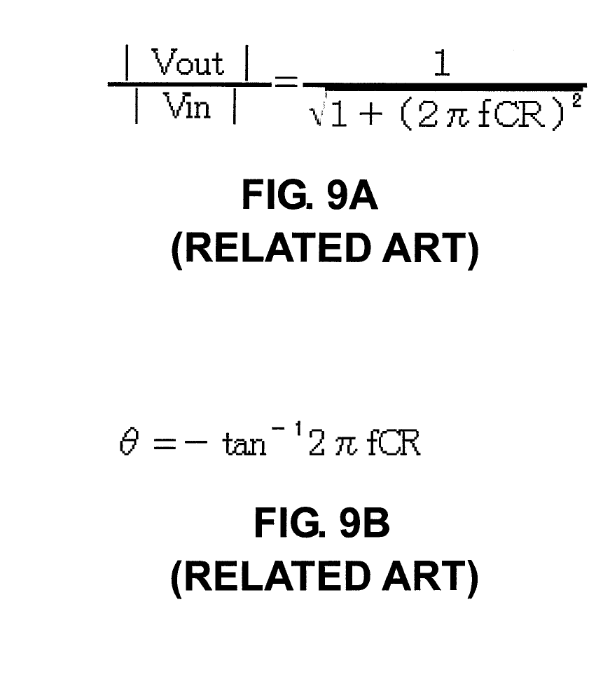

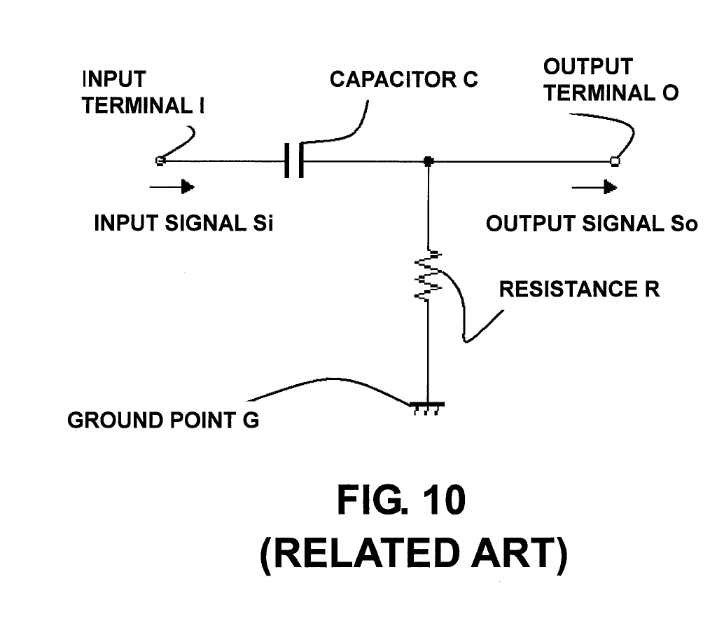

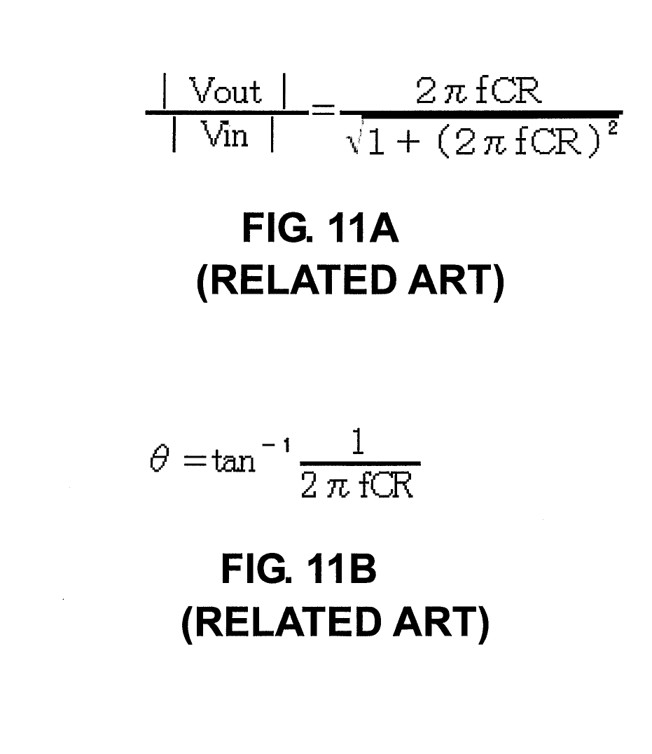

FIGS. 7A to 7D are formulae depicting: a frequency characteristic; a phase characteristic; a maximum phase advance frequency; and a maximum phase advance angle, respectively, obtained by a transfer function of the low-pass filter circuit 40. According to the frequency characteristic shown in FIG. 7A, as the resistance ratio (Nr) of the resistances of the filter circuit 40 becomes closer to 1/(1+A), an output level becomes lower as the frequency of the input signal becomes higher. According to the phase characteristic shown in FIG. 7B, the phase delay is 0 degree (output signal is in phase with the input signal) when the frequency is zero, and as the frequency of the input signal becomes higher, the phase delay is generated, increased, and then returns to 0 degree. The maximum phase delay frequency can be obtained, relative to the cutoff frequency fcA, by multiplying the cutoff frequency fcA with the reciprocal square root of the value obtained by subtracting the product of resistance ratio Nr and the amplification degree (1+A) of the positive phase amplifier 5 from 1, as shown in FIG. 7C. Here, Nr≦1/(1+A).

Similarly, as shown in FIG. 7D, the maximum phase delay angle of the maximum phase delay frequency is determined based on the resistance ratio Nr and the amplification degree (1+A) of the positive phase amplifier.

Accordingly, an active-type low-pass filter can be obtained having the phase characteristic in which, unlike the conventional low-pass filter, when the frequency of the input signal becomes higher, the phase advance of the output signal relative to the input signal increases by appropriately setting the resistance ratio Nr and the amplification degree “A” to use the frequency domain higher than the maximum phase delay frequency.

As described above, the filter circuit of the present invention performs filter processing in the frequency domain that is higher than (or lower than) the maximum phase delay frequency (or the maximum phase advance frequency) in the frequency domain higher (or lower) than the cutoff frequency. Thus, with the filter circuit of the present invention, the frequency characteristic can be used that could not be obtained with the conventional filter circuit.

The conventional filter circuit defines a certain frequency domain with a cutoff frequency and only outputs the frequencies included therein. The filter circuit of the present invention can also use the frequency domain that the conventional filter circuit is not designed to use. Thus, the phase characteristic can be corrected. With the filter circuit of the present invention, the frequency domain to be used can be determined with the resistance ratio or the capacitance ratio. Therefore, phase characteristics, which are different from those of the conventional filter circuit, appropriate for the frequency component of the signal to be processed can be used.

The filter circuit of the present invention has the phase characteristic with which an audio characteristic can be corrected in a simple way. If the filter circuit is used in the noise canceling system, the noise can be cancelled more effectively. If the filter circuit is used in noise canceling headphones, a noise canceling headphone with excellent audio characteristic can be obtained.

What is claimed is:

1. A filter circuit comprising:
an input terminal;
a first resistance;
a second resistance;
a capacitor; and
an output terminal, wherein
the first resistance, the second resistance, and the capacitor are connected in series in this order between the input terminal and a ground point,
the output terminal is provided at a connection point of the first resistance and the second resistance, and
a frequency domain is used that is higher than a maximum phase delay frequency higher than a cutoff frequency, the cutoff frequency being determined by a combined resistance value of the first and the second resistances and a capacitance value of the capacitor, so that when a frequency of an input signal becomes higher, a phase delay of an output signal relative to the input signal is reduced.

2. The filter circuit according to claim 1, wherein resistance values of the first and the second resistances are determined based on a certain ratio.

3. The filter circuit according claim 1, further comprising:
a positive phase amplifier for amplifying and outputting a signal output from the output terminal;
an inverting amplifier for amplifying and outputting a signal received from the input terminal; and
an adder for adding and outputting the output from the positive phase amplifier and the output from the inverting amplifier.

4. A filter circuit comprising:
an input terminal;
a variable resistance having three terminals;
a capacitor; and
an output terminal, wherein
the variable resistance and the capacitor are connected in series in this order between the input terminal and a ground point,
the output terminal is provided at an intermediate terminal of the variable resistance, and
a frequency domain is used that is higher than a maximum phase delay frequency higher than a cutoff frequency, the cutoff frequency being determined by a resistance value of the variable resistance and a capacitance value of the capacitor, so that when a frequency of an input signal becomes higher, a phase delay of an output signal relative to the input signal is reduced.

5. The filter circuit according claim 4, further comprising:
a positive phase amplifier for amplifying and outputting a signal output from the output terminal;
an inverting amplifier for amplifying and outputting a signal received from the input terminal; and
an adder for adding and outputting the output from the positive phase amplifier and the output from the inverting amplifier.

6. A filter circuit comprising:
an input terminal;
a first capacitor;
a second capacitor;
a resistance; and
an output terminal, wherein
the first capacitor, the second capacitor, and the resistance are connected in series in this order between the input terminal and a ground point,
the output terminal is provided at a connection point of the first capacitor and the second capacitor, and
a frequency domain is used that is lower than a maximum phase advance frequency lower than a cutoff frequency, the cutoff frequency being determined by a combined capacitance value of the first and the second capacitors and a resistance value of the resistance, so that when a frequency of an input signal becomes lower, a phase advance of an output signal relative to the input signal is reduced.

7. The filter circuit according to claim 5, wherein capacitance values of the first and the second capacitors are determined based on a certain ratio.
